(19) United States
(12) Patent Application Publication
(10) Pub. No.: US 2023/0398640 A1
(43) Pub. Date: Dec. 14, 2023

(54) MANUFACTURING METHOD OF WAFER

(71) Applicant: DISCO CORPORATION, Tokyo (JP)

(72) Inventor: Asahi NOMOTO, Tokyo (JP)

(21) Appl. No.: 18/325,480

(22) Filed: May 30, 2023

(30) Foreign Application Priority Data
Jun. 13, 2022 (JP) 2022-095025

(51) Int. Cl. B23K 26/53; B23K 26/0622; B23K 26/38; B23K 26/08; B23K 26/067

(52) U.S. Cl. CPC B23K 26/53; B23K 26/0622; B23K 26/38; B23K 26/0853; B23K 26/067; B23K 2101/40

(57) ABSTRACT

A manufacturing method of a wafer from a workpiece, the workpiece being an ingot of gallium nitride or a single-crystal substrate of gallium nitride having both a first surface and a second surface. The method includes a separation layer forming step of applying a pulsed laser beam with such a wavelength as to be transmitted through the workpiece to the first surface, and with a focal point of the laser beam positioned at a predetermined depth level in the workpiece, relatively moving the workpiece and the focal point along a predetermined direction, thereby forming a separation layer in the workpiece, and a separation step of separating the wafer from the workpiece using the separation layer as a start point. The predetermined direction forms, in a (0001) plane, an angle of 5° or smaller with respect to crystal orientations represented by the following Miller-Bravais indices (1).

[Math.1]

[symbol]

112̅0 [symbol] (1)

### BACKGROUND OF THE INVENTION

### Field of the Invention

The present invention relates to a manufacturing method of a wafer from a workpiece, which is an ingot of gallium nitride or a single-crystal substrate of gallium nitride having both a first surface and a second surface located on a side opposite to the first surface. The wafer has a thickness smaller than a distance between the first surface and the second surface.

### Description of the Related Art

Gallium nitride (GaN) is called a wide bandgap semiconductor, and has a bandgap approximately 3 times greater compared with silicon (Si). Making use of this relatively large bandgap of GaN, devices such as power devices and light-emitting diodes (LEDs) are manufactured. Single-crystal substrates (i.e., wafers) of GaN are generally manufactured by slicing an ingot of GaN. For the manufacture of such wafers, an annular slicer with cutting blade disposed on its inner peripheral portion rather than its outer peripheral portion is used, for example (see JP 2011-84469A).

However, the cutting blade of the slicer have a relatively large thickness (for example, 0.3 mm) compared with the thickness (for example, 0.15 mm) of each wafer. Taking a slicing margin and a wafer in combination, approximately 60% to 70% of the ingot is therefore disposed of as the slicing margin per wafer. As appreciated from the foregoing, the use of cutting blade leads to a relatively high percentage of a cutting margin (in other words, disposal rate) based on the total of the cutting margin and a wafer, and hence is uneconomical.

### SUMMARY OF THE INVENTION

With such a problem in view, the present invention has as an object thereof the provision of a wafer manufacturing method, which can reduce a slicing margin when manufacturing a wafer of GaN from an ingot of GaN or a single-crystal substrate of GaN.

In accordance with an aspect of the present invention, there is provided a manufacturing method of a wafer from a workpiece, the workpiece being an ingot of gallium nitride or a single-crystal substrate of gallium nitride having both a first surface and a second surface located on a side opposite to the first surface, and the wafer having a thickness smaller than a distance between the first surface and the second surface. The manufacturing method includes a holding step of holding the workpiece at the second surface thereof under suction, a separation layer forming step of, after the holding step, applying a pulsed laser beam with such a wavelength as to be transmitted through the workpiece to the first surface from a side opposite to the second surface, and with a focal point of the laser beam positioned at a predetermined depth level in the workpiece, relatively moving the workpiece and the focal point along a predetermined direction, thereby forming a separation layer in the workpiece, and a separation step of, after the separation layer forming step, separating the wafer from the workpiece using the separation layer as a start point. The predetermined direction in the separation layer forming step forms, in a (0001) plane, an angle of 5° or smaller with respect to crystal orientations represented by the following Miller-Bravais indices (1).

[Math.1]

[symbol]

112̅0 [symbol] (1)

Preferably, the manufacturing method may further include, after the holding step and before the separation layer forming step, an annular processing step of positioning the focal point at the predetermined depth level and applying the laser beam in an annular pattern along an outer peripheral edge of the workpiece, thereby forming an annular separation layer in an outer peripheral region of the workpiece.

Preferably, in the separation layer forming step, after the workpiece and the focal point have been relatively moved in a regular hexagonal pattern so as to follow the predetermined direction, the focal point may be moved toward a center in a radial direction of the workpiece, and the workpiece and the focal point may then be relatively moved in a smaller regular hexagonal pattern so as to follow the predetermined direction.

Preferably, in the separation layer forming step, the laser beam may be split into a plurality of laser beams, individual focal points of the respective laser beams may be arranged so that the focal points are aligned side by side along a first direction, and a second direction orthogonal to the first direction may be set to be the predetermined direction.

Preferably, in the separation layer forming step, the focal points may be moved along the second direction, may then be moved along the first direction, and may thereafter be moved along the second direction, and when the focal points are moved along the first direction, the workpiece and the focal points may be relatively moved along the first direction so that a first moving region, the first moving region including trajectories of the movement of the focal points along the second direction, and a second moving region, the second moving region including trajectories of the movement of the focal points along the second direction after the movement of the focal points along the first direction, partially overlap each other as seen in the first surface.

Preferably, in the separation layer forming step, the focal points may be arranged side by side along the first direction at a spacing of 5 μm or greater and 20 μm or smaller.

Preferably, in the separation layer forming step, separation layers may be formed in the first moving region and the second moving region, respectively, and may each contain a plurality of modified regions, and in each separation layer, the modified regions may have an aspect ratio of 0.5 or greater and 3.0 or smaller, the aspect ratio being represented by (b/a) where “a” denotes a spacing (μm) between the modified regions formed side by side along the first direction and “b” denotes a spacing (μm) between the modified regions formed side by side along the second direction by relatively moving the focal points and the workpiece along the second direction.

Preferably, in the separation layer forming step, the laser beam to be applied to the workpiece may be applied in a burst mode to the workpiece.

In the manufacturing method according to the aspect of the present invention, with the focal point of the laser beam including such the wavelength as to be transmitted through the workpiece positioned at the predetermined depth level in the workpiece, the workpiece and the focal point are relatively moved along the predetermined direction, whereby the separation layer is formed in the workpiece (separation layer forming step). The wafer is then separated from the workpiece using the separation layer as the start point (separation step). Owing to the use of the laser beam, the thickness of the separation layer can be controlled, for example, to approximately 60 μm (i.e., 0.06 mm). Compared with the case in which cutting blade are used, it is thus possible to reduce the slicing margin in the thickness direction of the workpiece.

The above and other objects, features and advantages of the present invention and the manner of realizing them will become more apparent, and the invention itself will best be understood from a study of the following description and appended claims with reference to the attached drawings showing some preferred embodiments and a modification of the invention.

### BRIEF DESCRIPTION OF THE DRAWINGS

FIG. 1 is a flow diagram of a manufacturing method according to a first embodiment of the aspect of the present invention;

FIG. 2 is a perspective view of an ingot to which the manufacturing method of FIG. 1 is applied;

FIG. 3 is a schematic diagram of a laser processing apparatus for applying laser processing to the ingot of FIG. 2;

FIG. 4A is a schematic representation of a pulsed laser beam that enters from a laser oscillator to an acousto-optic modulator of the laser processing apparatus of FIG. 3;

FIG. 4B is a schematic representation of a pulsed laser beam that enters from the acousto-optic modulator to a power adjustment unit of the laser processing apparatus of FIG. 3;

FIG. 5 is a side view depicting a holding step of the manufacturing method of FIG. 1;

FIG. 6 is a plan view depicting a separation layer forming step of the manufacturing method of FIG. 1;

FIG. 7 is a plan view depicting an overlap between moving regions of a plurality of focal points in the separation layer forming step of FIG. 6;

FIG. 8A is a fragmentary front view of a separation device, and depicts a separation step of the manufacturing method of FIG. 1;

FIG. 8B is a fragmentary front view of the separation device, and depicts a wafer separated from the ingot in the separation step of FIG. 8A;

FIG. 9 is a plan view depicting a modification of the separation layer forming step of FIG. 6;

FIG. 10 is a flow diagram of a manufacturing method according to a second embodiment of the aspect of the present invention;

FIG. 11 is a plan view depicting an annular processing step of the manufacturing method of FIG. 10;

FIG. 12 is a photograph of a single-crystal substrate with no sufficient cracks formed between modified regions in a first experiment of the separation layer forming step of the manufacturing method according to the first embodiment as depicted in FIG. 1;

FIG. 13 is a diagram schematically depicting the modified regions in the first experiment;

FIG. 14 is a photograph of a single-crystal substrate with relatively large cracks formed in a c-axis direction in a second experiment; and

FIG. 15 is a photograph of a single-crystal substrate with sufficient cracks formed between modified regions in a third experiment.

### DETAILED DESCRIPTION OF THE PREFERRED EMBODIMENTS

With reference to the attached drawings, a description will be made about a first and second embodiment of the aspect of the present invention and a modification of the first embodiment.

### First Embodiment

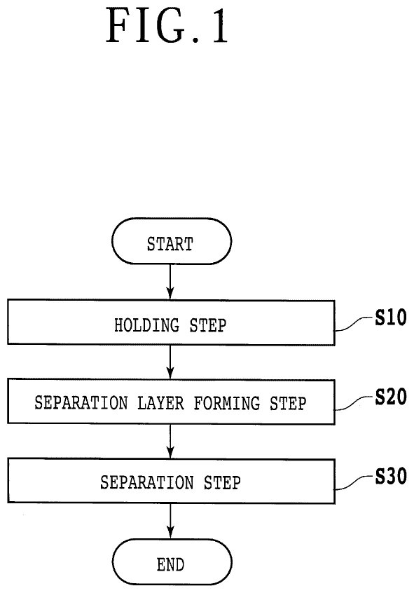

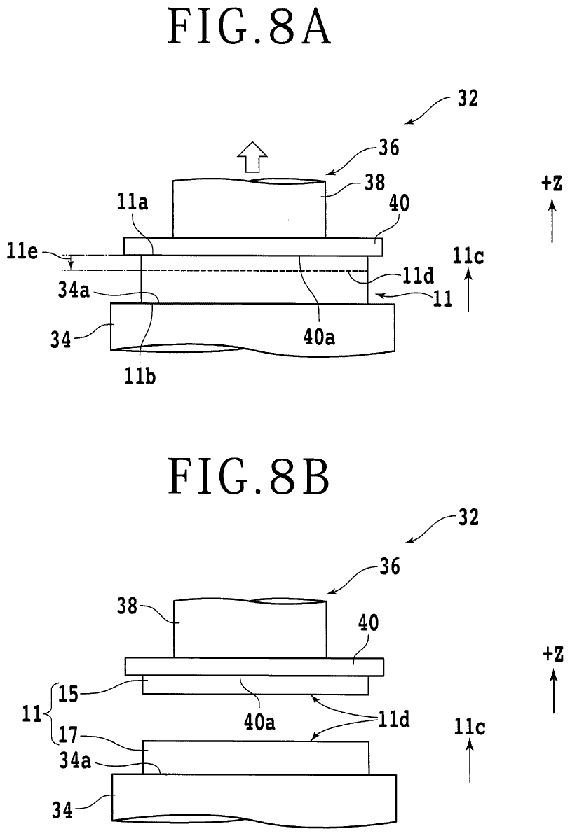

FIG. 1 is a flow diagram of a manufacturing method according to the first embodiment, which manufactures, from an ingot 11 of GaN (workpiece), a single-crystal substrate of GaN (specifically, a wafer (see FIG. 8B) thinner than the ingot 11. In the first embodiment, the wafer 15 is manufactured by successively performing a holding step S10, a separation layer forming step S20, and a separation step S30, all of which are depicted in FIG. 1.

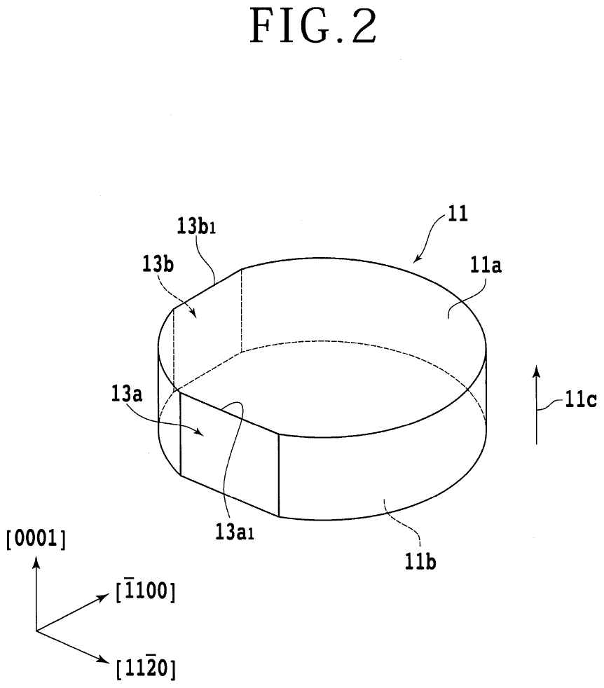

Referring to FIG. 2, a description will first be made about the ingot 11. FIG. 2 is a perspective view of the ingot 11. The ingot 11 is a single crystal of GaN, which has a hexagonal crystal structure. However, no particular limitation is imposed on the conductivity type of the ingot 11. The ingot 11 may be of p-type containing a p-type dopant such as magnesium (Mg) or beryllium (Be), or may be of n-type containing an n-type dopant such as silicon (Si) or germanium (Ge). The ingot 11 in this embodiment has a diameter of 4 inches (approximately 100 mm) and a thickness of 500 μm, although its diameter and thickness are not limited to these values. The ingot 11 has a first surface 11a, and a second surface 11b that is located on a side opposite to the first surface 11a in a thickness direction 11c and is parallel to the first surface 11a. The first surface 11a corresponds to the c-plane represented by the following Miller-Bravais indices (2).

[Math.2]

(0001) (2)

Crystal planes and crystal orientations are herein specified using Miller-Bravais indices. Specific crystal planes are represented using the notation ( ) while crystal planes that are equivalent to one another because of the symmetry of the crystal structure are represented using the notation { }. Similarly, specific crystal orientations are represented using the notation [ ], while crystal orientations that are equivalent to one another are represented using the notation < >. A crystal orientation that is perpendicular to the first surface 11a (c-plane) and is directed upward is represented by the below-described Miller-Bravais indices (3). This crystal orientation is called “the c-axis,” and corresponds to the thickness direction 11c of the ingot 11.

[Math.3]

(3)

The ingot 11 in this embodiment has a plurality of planar facets on its side surface. Described more specifically, the ingot 11 has a first side surface 13a and a second surface 13b, which are in a mutually orthogonal positional relation. The first side surface 13a corresponds to a crystal plane represented by the following Miller-Bravais indices (4), while the second side surface 13b corresponds to a crystal plane represented by the following Miller-Bravais indices (5).

[Math.4]

(1̅100) (4)

[Math.5]

(112̅0) (5)

A first orientation flat (hereinafter abbreviated as “the first OF 13a₁”), at which the first surface 11a and the first side surface 13a intersect, is parallel to a crystal orientation of the following Miller-Bravais indices (6).

[Math.6]

[112̅0] (6)

On the other hand, a second orientation flat (hereinafter abbreviated as “the second OF 13b₁”), at which the first surface 11a and the second side surface 13b intersect, is parallel to a crystal orientation of the following Miller-Bravais indices (7).

[Math.7]

(7)

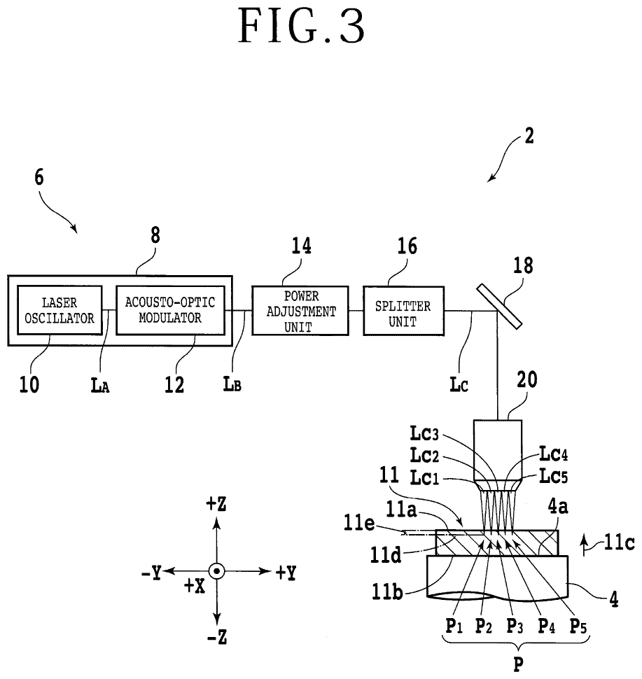

Referring to FIG. 3, a description will next be made about a laser processing apparatus 2 for applying laser processing to the ingot 11. FIG. 3 is a schematic diagram of the laser processing apparatus 2. In FIG. 3, a plurality of elements is indicated by function blocks or simplified shapes. An X-axis direction (processing feed direction, second direction, predetermined direction), a Y-axis direction (indexing feed direction, first direction) and a Z-axis direction (height direction), all depicted in FIG. 3, are orthogonal to one another. It is to be noted that the X-axis direction is herein parallel to a +X direction and a −X direction, which are directed opposite to each other. Similarly, the Y-axis direction is parallel to a +Y direction and a −Y direction, which are directed opposite to each other, and the Z-axis direction is parallel to a +Z direction and a −Z direction, which are directed opposite to each other.

The laser processing apparatus 2 has a disk-shaped chuck table 4. The chuck table 4 has a disk-shaped frame body formed with a metal such as stainless steel. At a central portion of the frame body, a disk-shaped recess (not depicted) of a smaller diameter than the diameter of the frame body is formed. In this recess, a disk-shaped porous plate formed with porous ceramics is fixed. In the frame body, predetermined flow channels (not depicted) are formed, to which a suction source (not depicted) such as a vacuum pump is connected via a pipe member (not depicted) or the like. When a negative pressure produced at the suction source is transmitted to the porous plate, the negative pressure occurs in a circular upper surface of the porous plate.

An annular upper surface of the frame body and the circular upper surface of the porous plate are substantially flush with each other and are substantially planar, and function as a holding surface 4a for holding the ingot 11 under suction. The holding surface 4a is arranged in parallel with an XY plane.

The chuck table 4 is provided at a lower portion thereof with a rotary drive mechanism (not depicted) to rotate the chuck table 4. The rotary drive mechanism can rotate the chuck table 4 a predetermined angle about a predetermined axis of rotation, which extends along the Z-axis direction. The chuck table 4 and rotary drive mechanism are supported on a horizontal moving mechanism (not depicted). The horizontal moving mechanism includes an X-axis moving mechanism and a Y-axis moving mechanism, each of which is of a ball screw type, and can move the chuck table 4 and rotary drive mechanism along the X-axis direction and Y-axis direction.

Above the holding surface 4a, a laser beam irradiation unit 6 is disposed. The laser beam irradiation unit 6 has a laser beam generation unit 8. The laser beam generation unit 8 includes a laser oscillator 10. The laser oscillator 10 has, for example, Nd:YAG, Nd:YVO₄, or the like as a laser medium. From the laser oscillator 10, a pulsed (for example, several tens MHz) laser beam L_{A} with such a wavelength as to be transmitted through the ingot 11 of GaN (for example, 1,064 nm) is emitted.

The laser beam L_{A} emitted from the laser oscillator 10 is converted to a burst mode laser beam L_{B} at an acousto-optic modulator (AOM) 12. The acousto-optic modulator 12 is operated by an electrical signal inputted thereto, and deflects the laser beam L A for only a predetermined time according to the signal. As a consequence, the laser beam L_{B} in a form that the laser beam L_{A} has been repeatedly thinned out for a predetermined time interval is emitted from the acousto-optic modulator 12 to a power adjustment unit 14.

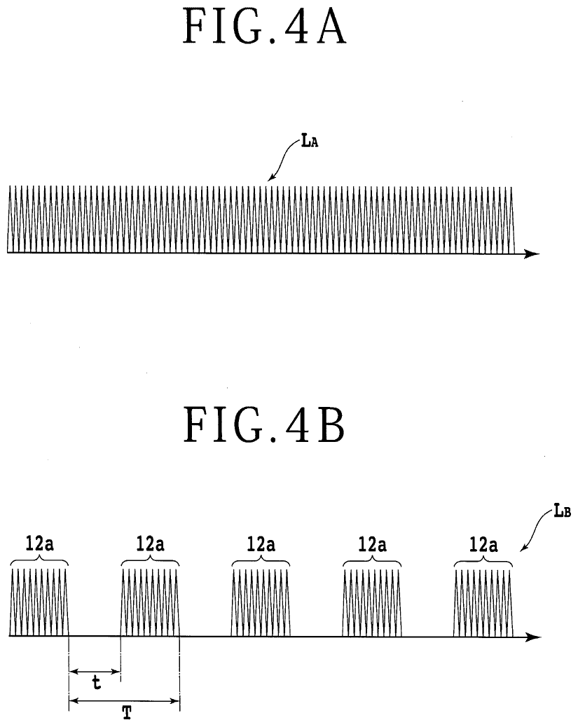

FIG. 4A is a schematic representation of the pulsed laser beam L_{A} that enters from the laser oscillator 10 to the acousto-optic modulator 12, and FIG. 4B is a schematic representation of the pulsed laser beam L_{B} that enters from the acousto-optic modulator 12 to the power adjustment unit 14. In each of FIGS. 4A and 4B, the abscissa represents the time, and the ordinate represents the level of power. As depicted in FIG. 4B, the laser beam L_{A} is converted at the acousto-optic modulator 12 to the burst mode laser beam L_{B} that a pulse group 12a, including a plurality of pulses, is repeated at a predetermined cycle T. A time interval t that corresponds to a spacing between pulse groups 12a is, for example, several tens μs to several hundreds μs. It is to be noted that the inverse of the cycle T between the pulse groups 12a as repetition units (in other words, the repetition frequency) is, for example, 50 kHz.

Referring back to FIG. 3, the laser beam L_{B} is then adjusted to an appropriate power by the power adjustment unit 14 including an attenuator or the like and after that, the resulting laser beam L B is spatially split at a splitter unit 16. The splitter unit 16 in this embodiment has a liquid crystal on silicon-spatial light modulator (LCOS-SLM) (not depicted), but a diffraction grating may be also used in place of the LCOS-SLM. A laser beam L_{C} that has passed through the splitter unit 16 is guided to an irradiation head 20 by way of a collimator lens (not depicted), a mirror 18, and the like. The irradiation head 20 has a condenser lens (not depicted). The condenser lens focuses the laser beam L_{C} at a predetermined depth level in the ingot 11 held under suction on the holding surface 4a.

The laser beam L_{C} depicted in FIG. 3 has been split by the splitter unit 16 into a plurality of laser beams L_{C1}, L_{C2}, L_{C3}, L_{C4} and L_{C5}, and focal points Ps (P₁, P₂, P₃, P₄, P₅) of the respective laser beams L_{C1} to L_{C5} are arranged so that they are aligned side by side in the Y-axis direction at the predetermined depth level in the ingot 11. The spacing between the focal points Ps aligned side by side along the Y-axis direction is set at a predetermined value, for example, of 5 μm or greater and 20 μm or smaller. It is to be noted that in the example depicted in FIG. 3, the split number of the laser beam L_{C} is set at 5 for the sake of convenience in description, but the split number is not limited to 5. The split number may be 2 or greater and 16 or fewer, with the split number in a preferred example being 10.

In a casing (not depicted) of the laser beam irradiation unit 6, an imaging unit (not depicted) is disposed to image an object. The imaging unit has a light-emitting device (not depicted) that emits light downward along the Z-axis direction. The light-emitting device includes light-emitting elements such as LEDs that function as a light source. The imaging unit further has an imaging device (not depicted) that receives via a lens (not depicted) the reflected light of the light applied from the light-emitting device. The light from the light-emitting device has the wavelengths of visible light. The imaging device can photoelectrically convert the frequencies of the light from the light-emitting device. The imaging device is a charge-coupled device (CCD) image sensor, a complementary metal-oxide-semiconductor (CMOS) image sensor, or the like. The light-emitting device, lens, imaging device, and the like make up a microscope camera unit that images objects with visible light.

Operations of the above-mentioned chuck table 4, rotary drive mechanism, horizontal moving mechanism, laser beam irradiation unit 6, and the like are controlled by a controller (not depicted). The controller includes a computer that includes, for example, a processor (processing unit) represented by a central processing device (CPU), and memories (storage devices). The memories include a main storage device such as a dynamic random access memory (DRAM), a static random access memory (SRAM), or a read only memory (ROM), and an auxiliary storage device such as a flash memory, a hard disk drive, or a solid state drive. In the auxiliary storage device, software including predetermined programs is stored. Functions of the controller are realized by operating the processing device and the like according to the software.

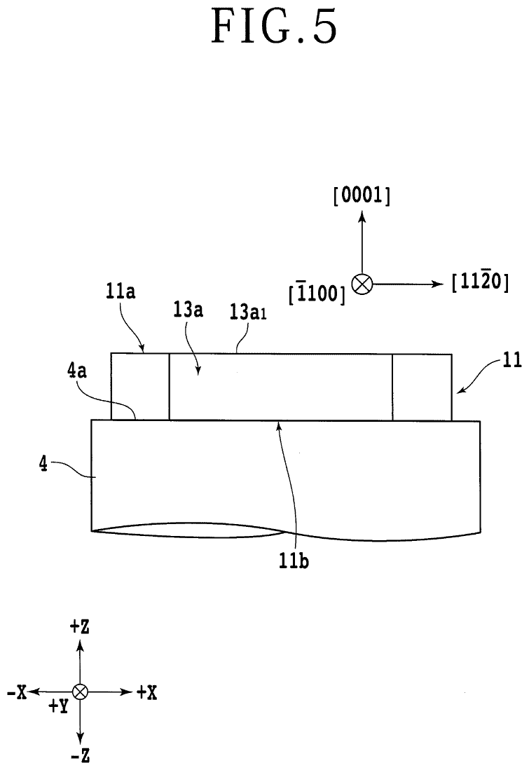

Following the steps depicted in FIG. 1, a description will next be made about the manufacturing method according to the first embodiment for the wafer FIG. 5 is a side view depicting the holding step S10 of holding the ingot 11 at the second surface 11b under suction on the holding surface 4a. In the holding step S10, the ingot 11 is held under suction on the holding surface 4a so that the second surface 11b is kept in contact with the holding surface 4a and the first surface 11a is exposed upward. In the holding step S10, the ingot 11 is also imaged on a side of the first surface 11a by the imaging unit after its holding under suction, thereby specifying any deviation of the first OF 13a₁ relative to the X-axis direction of the laser processing apparatus 2. Subsequently, the chuck table 4 is rotated by the rotary drive mechanism so as to cancel out the deviation, whereby the first OF 13a₁ is made substantially parallel to the X-axis direction.

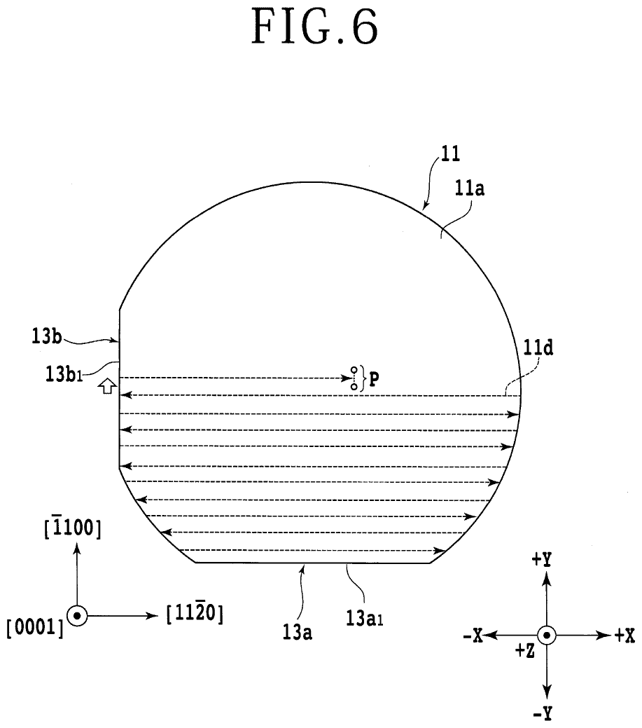

After the first step S10, the burst mode laser beam L_{C} is applied from above the first surface 11a (in other words, from the side opposite to the second surface 11b) toward the first surface 11a, so that a separation layer 11d (see FIG. 8A) is formed at the predetermined depth level from the first surface 11a. FIG. 6 is a plan view depicting the separation layer forming step S20. It is to be noted that in FIG. 6, with a view to facilitating understanding, two of the focal points Ps, the two focal points being located uppermost and lowermost in the Y-axis direction, are depicted by relatively large circles, and the remaining focal points located between the two focal points Ps are depicted by small dots.

In the separation layer forming step S20, with the respective focal points Ps arranged so that they are aligned side by side along the Y-axis direction at a predetermined depth level 11e (see FIGS. 3 and 8A) in the ingot 11, the focal points Ps and the ingot 11 (in other words, the chuck table 4) are relatively moved along the X-axis direction (predetermined direction). In the separation layer forming step S20 in this embodiment, the focal points Ps are relatively moved in the +X direction and are then indexed and fed along the Y-axis direction, and are next moved in the −X direction. In this manner, the movement of the focal points Ps in the +X direction and their movement in the −X direction are alternately repeated.

In FIG. 6, a moving path of one of the focal points Ps in the ingot 11, the one focal point being located at a middle in the Y-axis direction, is depicted by a dotted arrow. It is to be noted that the focal points Ps may be moved in only the +X or −X direction instead of moving them alternately in the +X and −X directions. If the direction of the relative movement of the focal points Ps and the ingot 11 conforms to the X-axis direction, the direction of their relative movement is parallel to crystal orientations represented by the following Miller-Bravais indices (8).

[Math.8]

[112̅0],[1̅1̅20] (8)

The two crystal orientations represented by the Miller-Bravais indices (8) are two of six equivalent crystal orientations in the ingot 11 having the hexagonal crystal structure as represented by the following Miller-Bravais indices (9).

[Math.9]

[symbol]

112̅0 [symbol] =[112̅0],[1̅21̅0],[2̅110],[1̅1̅20],[12̅10],[21̅1̅0] (9)

However, the direction of the relative movement of the focal points Ps and the ingot 11 is not absolutely required to be completely parallel to the crystal orientations specified by the Miller-Bravais indices (8), and in the c-plane (see the above-mentioned Miller-Bravais indices (2)), may form an angle of 5° or smaller with respect to the crystal orientations specified by the Miller-Bravais indices (8). The inventor has confirmed through experiments that a separation layer 11d is formed even in this case. Examples of processing conditions for use in the separation layer forming step S20 will be given below.

Wavelength: 1,064 nm

Processing feed rate: 875 mm/s

Indexing feed rate: 106 μm (i.e., index amount)

Repetition frequency: 50 kHz

Burst number: 10 (the number of pulses contained in each pulse group 12a)

Split number:10 (split number of the laser beam L_{C})

Pass number: 1

Spot diameter at each focal point: approximately 5 μm

Depth level of focal points: 170 μm from the first surface 11a

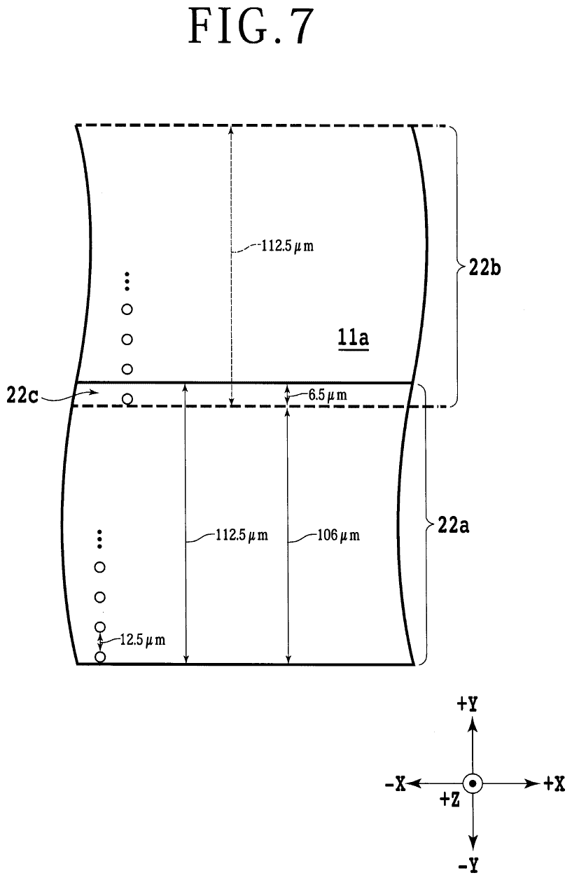

Under these conditions, the spacing between each adjacent two focal points in the ten focal points is set, for example, at 12.5 μm. If the ten focal points Ps are arranged, the laser beam L_{C} is applied in a range of 12.5 μm×9, so that the overall width of application at the ten focal points Ps arranged along the Y-axis direction is 112.5 μm (see FIG. 7).

If the focal points Ps are relatively moved along the X-axis direction, the trajectories of the movement of the focal points Ps are contained in a first moving region 22a indicated by solid lines. After the focal points Ps have been moved along the X-axis direction, the irradiation head 20 and the chuck table 4 are relatively moved along the Y-axis direction, whereby indexing feed is performed by the above-mentioned predetermined index amount. In this state, the focal points Ps are similarly and relatively moved along the X-axis direction. The trajectory of the movement of the one of the focal points Ps, the one focal point being located at the middle in the Y-axis direction, after the indexing feed is contained in a second moving region 22b (see FIG. 7) indicated by dashed lines. As depicted in FIG. 7, the first moving region 22a and the second moving region 22b partially overlap each other at an overlapping region 22c as seen in the first surface 11a.

FIG. 7 is a plan view depicting an overlap between the first moving region 22a and the second moving region 22b. Under the processing conditions mentioned above, the width in the Y-axis direction of the overlap is 6.5 μm. It is to be noted that such overlapping regions 22c are formed on both sides in the Y-axis direction of each moving region except for two moving regions located at opposite end portions in the Y-axis direction of the first surface 11a. Now, in a vicinity of each of the focal points Ps, the crystallinity of the ingot 11 changes through multiphoton absorption. In a region where multiphoton absorption has occurred, a modified region is formed, for example, with mechanical strength lowered compared with that of a region where no multiphoton absorption has occurred. In addition, cracks propagate from the modified region along an XY plane direction. Depending on the processing conditions, however, cracks may propagate from a modified region along Z-axis direction. In this embodiment, a region inside the ingot 11, where modified regions and cracks have been formed, is called “the separation layer 11d.”

After the separation layer forming step S20, the ingot 11 is separated into the wafer 15 and a remaining ingot 17 using a separation device 32 (separation step S30) as depicted in FIGS. 8A and 8B. With reference to FIG. 8A, a description will be made about the separation device 32. The separation device 32 has a chuck table 34 of substantially the same diameter as the above-mentioned chuck table 4. The chuck table 34 has substantially the same construction as the chuck table 4, and the chuck table 34 has an upper surface that functions as a holding surface 34a for holding the ingot 11 under suction. Above the chuck table 34, a separation unit 36 is disposed.

The separation unit 36 has a cylindrical movable portion 38 with a length portion thereof arranged along the Z-axis direction. To the movable portion 38, a Z-axis moving mechanism (not depicted) is connected, so that the movable portion 38 is movable along the Z-axis direction. The Z-axis moving mechanism is, for example, a moving mechanism of a ball screw type, but may include an actuator of another type. On a bottom part of the movable portion 38, a disk-shaped suction head 40 is disposed. Similar to the chuck table 34, the suction head 40 has a frame body and a porous plate. Lower surfaces of the frame body and porous plate are arranged substantially flush with each other and substantially parallel to the XY plane, and function as a holding surface 40a.

FIG. 8A is a view depicting the separation step S30. In the separation step S30, the ingot 11 with the separation layer 11d formed therein is held at the second surface 11b thereof under suction on the holding surface 34a of the chuck table 34, and at the same time, is held at the first surface 11a thereof under suction on the holding surface 40a of the suction head 40. Next, an external force is applied to the ingot 11. The application of the external force is performed by driving one or more wedges (not depicted) into the side surface of the ingot 11 at the height position of the separation layer 11d. It is preferred to drive the one or more wedges into the side surface of the ingot 11 at a like plurality of locations spaced apart from one another along a peripheral direction of the ingot 11 rather than driving a single wedge into the side surface of the ingot 11 at only a single location.

Owing to the application of the external force, the cracks are allowed to propagate further in the XY plane direction at the depth level 11e where the separation layer 11d is formed. The external force may also be applied by applying ultrasonic waves (specifically, elastic vibration waves in a frequency band exceeding 20 kHz) to the ingot 11 instead of driving the one or more wedges.

If ultrasonic waves are applied, the ultrasonic waves are applied to the side of the first surface 11a via liquid such as pure water before holding the ingot 11 at the first surface 11a thereof on the holding surface 40a of the suction head 40. Described specifically, liquid is ejected from a nozzle against the ingot 11 while applying ultrasonic waves, or ultrasonic waves are applied from a horn to the side of the first surface 11a via liquid. The inventor has confirmed through experiments that unfavorable cracks occur if an external force is applied at once to the entirety on the side of the first surface 11a.

If the nozzle or horn is used, an external force is therefore first applied to a local region of approximately 5 mm to 50 mm in diameter on the side of the first surface 11a while using ultrasonic waves. The nozzle or horn and the chuck table 34 are then relatively moved, so that the external force is applied to another region on the side of the first surface 11a. By gradually widening the region, to which the external force is to be applied, as described above, the cracks between the modified regions are allowed to propagate along the first surface 11a.

Owing to the application of the external force, the cracks themselves are connected together between the adjacent modified regions, and therefore the mechanical strength of the separation layer 11d becomes still weaker compared with the regions other than the separation layer 11d in the ingot 11. Accordingly, the wafer 15 can be separated from the ingot 11 with a smaller force compared with a case where no external force is applied. After the external force has been applied, the suction head 40 is raised (in other words, is moved in the +Z direction). As a consequence, the wafer 15 is separated from the ingot 11 using the separation layer 11d as a start point.

FIG. 8B is a view depicting the wafer 15 separated from the ingot 11. It is to be noted that the above-mentioned application of the external force may be performed concurrently with the rise of the suction head 40. The separation layer 11d has a thickness of approximately 50 μm to 60 μm (for example, 58 μm) in the thickness direction 11c, and this thickness of the separation layer 11d corresponds to the above-mentioned slicing margin.

The laser slicing of the ingot 11 can reduce the slicing margin in the thickness direction 11c of the ingot 11 compared with a case in which a slicer is used. The productivity of the wafer 15 is therefore improved when manufacturing the wafer 15 from the ingot 11. It is to be noted that a slicing margin of at least approximately 150 μm is needed even when a wire saw is used. The manufacturing method of this embodiment is hence superior even compared with the use of a wire saw.

In the above-mentioned example, it is described to form the separation layer 11d by arranging the focal points Ps at the predetermined depth level 11e in the ingot 11. However, it is possible to form a separation layer 11d at a predetermined depth level in a single-crystal substrate (workpiece) of GaN instead of the ingot 11, and to separate a wafer 15 from this single-crystal substrate. In this case, the single-crystal substrate of GaN is needed to have a thickness greater than the thickness (in other words, the length in the direction of the c-axis) of the wafer 15 to be separated. In other words, the thickness of the wafer 15 is smaller than the distance between the both surfaces (the first surface and second surface) in the direction of the c-axis of the single-crystal substrate of GaN.

### <Modification>

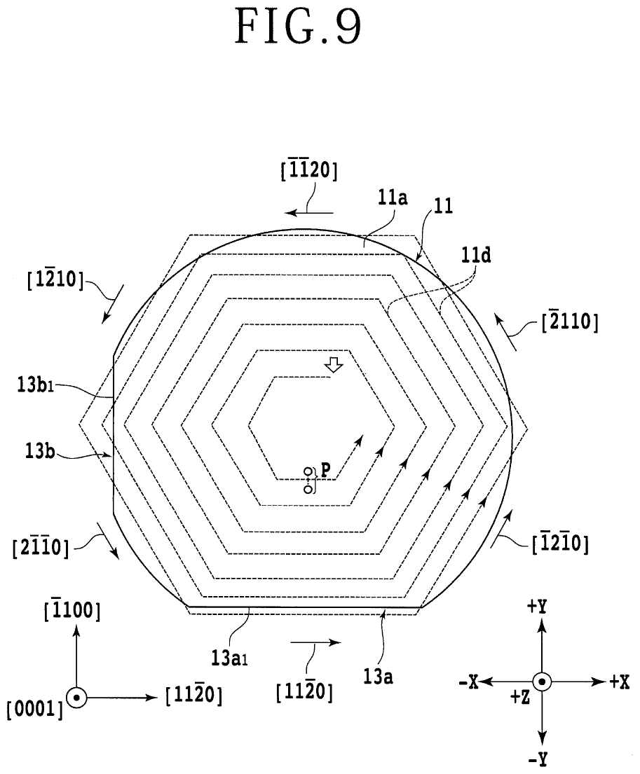

Next, a description will be made about the modification of the separation layer forming step S20. FIG. 9 is a view depicting the modification of the separation layer forming step S20. In the separation layer forming step S20 according to the modification, the relative movement of the focal points Ps and an ingot 11 at the above-mentioned processing feed rate is not linear along the X-axis direction, but takes place in a pattern of a plurality of concentric regular hexagons. It is here that the modification is different from the first embodiment, and in the remaining respects, the modification is the same as the first embodiment. For example, the focal points Ps are relatively moved in the order of the below-described Miller-Bravais indices (10), (11), (12), (13), (14) and (15). Such processing can be realized, for example, through an appropriate combination of linear movement of the chuck table 4 by the horizontal moving mechanism and rotation of the chuck table 4 by the rotary drive mechanism.

[Math.10]

[1̅1̅20] (10)

[Math.11]

[12̅10] (11)

[Math.12]

[21̅1̅0] (12)

[Math.13]

[112̅0] (13)

[Math.14]

[1̅21̅0] (14)

[Math.15]

[2̅110] (15)

After the focal points Ps have been relatively moved so as to draw a single regular hexagon, with the focal points Ps moved by the above-mentioned predetermined index amount toward a center in a radial direction of the ingot 11, the focal points Ps are similarly relatively moved in the order of from the Miller-Bravais indices (10) to the Miller-Bravais indices (15). As a consequence, moving regions of the focal points Ps take a form of a plurality of concentrically arranged hexagons as depicted in FIG. 9. It is to be noted that, as indicated by the Miller-Bravais indices (9), the Miller-Bravais indices (10) to the Miller-Bravais indices (15) are all included in the crystal orientations represented by the Miller-Bravais indices (1).

In this modification, the focal points Ps are moved in the crystal orientation represented by the Miller-Bravais indices (10) at the start of laser processing. However, the laser processing may be started in any one of the Miller-Bravais indices (10) to (15) insofar as the focal points Ps can be relatively moved in a regular hexagonal pattern. Further, the direction of the relative movement of the focal points Ps and the ingot 11 is not absolutely required to be completely parallel to the crystal orientations specified by the Miller-Bravais indices (1), and in the c-plane, may form an angle of 5° or smaller with respect to the crystal orientations specified by the Miller-Bravais indices (1).

If the focal points Ps and the ingot 11 are relatively moved along the crystal orientation specified by the Miller-Bravais indices (10), for example, the direction of this relative movement can form, in the c-plane, an angle of 5° or smaller with respect to the crystal orientation specified by the Miller-Bravais indices (10). This applies equally to a case in which the focal points Ps and the ingot 11 are relatively moved along any one of the crystal orientations specified by the Miller-Bravais indices (11) to (15). This modification can be also similarly applied to a single-crystal substrate of GaN instead of the ingot 11.

### Second Embodiment

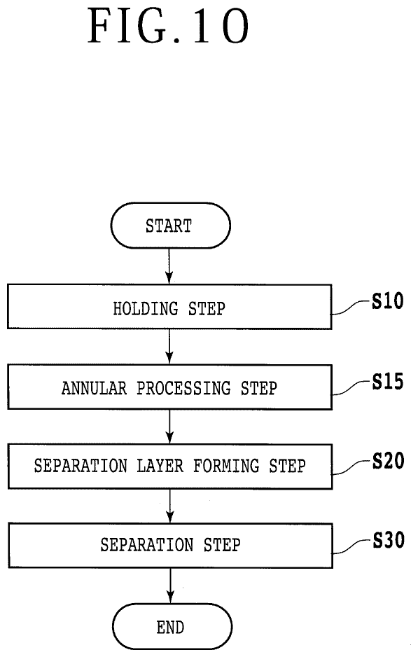

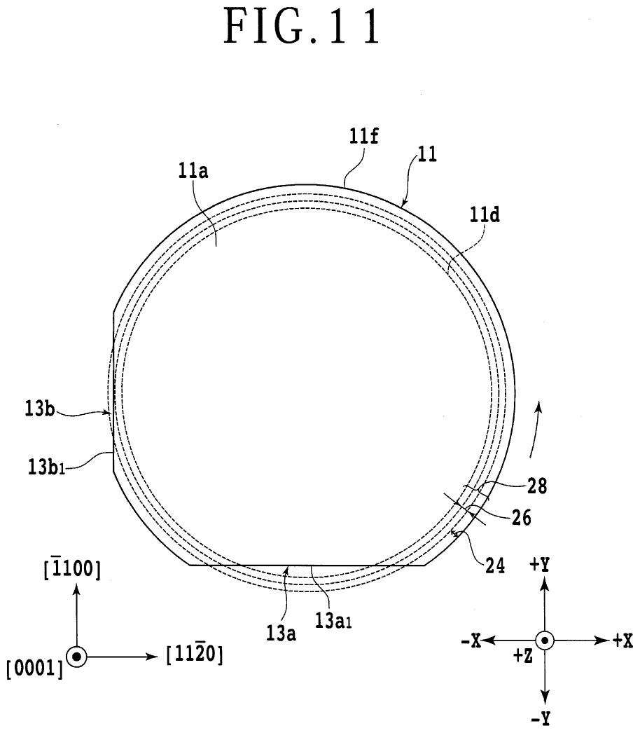

Referring to FIGS. 10 and 11, a description will next be made about the second embodiment. FIG. 10 is a flow diagram of a manufacturing method according to the second embodiment for a wafer 15, and FIG. 11 is a plan view depicting an annular processing step S15. The manufacturing method according to the second embodiment further includes, after the holding step S10 and before the separation layer forming step S20, the annular processing step S15 to apply the laser beam L_{C} in an annular pattern along an outer peripheral edge 11f of an ingot 11. In this embodiment, the expression “to apply the laser beam L_{C} in an annular pattern along an outer peripheral edge 11f” means that, considering that an edge of the first surface 11a, the edge missing in parts for the presence of a first OF 13a₁ and a second OF 13b₁, has been complemented so as to form a circle, the laser beam L_{C} is applied so as to follow the complemented circular edge of the first surface 11a.

In the annular processing step S15, the focal points Ps are also positioned at the same predetermined depth level 11e as in the formation of the separation layer 11d in the separation layer forming step S20. In the annular processing step S15, the focal points Ps are first arranged side by side so that the focal points Ps are aligned along the Y-axis direction at the predetermined depth level 11e in the ingot 11. It is to be noted that at this time, one of the focal points Ps, the one focal point being to locate on an outermost side, is positioned, for example, on a side inner by a predetermined distance 24 from the outer peripheral edge 11f in a radial direction of the ingot 11. The predetermined distance is, for example, 4 μm or greater and 8 μm or smaller, with a suitable example being 5 μm or greater and 6 μm or smaller.

In this state, the chuck table 4 is rotated a full turn at a predetermined rotational speed in the direction of an arrow depicted in FIG. 11. After the full turn, the focal points Ps are moved inward in the radial direction of the ingot 11. Described specifically, the chuck table 4 is indexed and fed by a predetermined index amount 26 along the Y-axis direction. The predetermined index amount 26 is, for example, 106 μm. The predetermined rotational speed of the chuck table 4 is suitably adjusted, for example, so that the focal points Ps have a peripheral speed substantially equal to the above-mentioned processing feed rate. The predetermined rotational speed of the chuck table 4 may be adjusted so as to realize the below-described suitable aspect ratio (b/a).

In the annular processing step S15, one or more separation layers 11d are also formed in an outer peripheral region 28 of the ingot 11 as described above. FIG. 11 depicts the example in which three annular separation layers 11d are concentrically formed by rotating the chuck table 4 three full turns, but the number of turns is not limited to 3. Other processing conditions (wavelength, repetition frequency, burst number, split number, pass number, spot diameter at each focal point, depth level of focal points) are set, for example, equal to those in the first embodiment. This allows smooth performance of the separation layer forming step S20 after the annular processing step S15.

When separation layers 11d are formed in the separation layer forming step S20, the bonds between Ga and N atoms are broken off, so that N₂ (nitrogen molecules) are formed and nitrogen gas is given off. Unless the separation layers 11d have been formed in the outer peripheral region 28 through the annular processing step S15, there is a possibility that one or more abnormal volume expansion regions may be formed inside in the radial direction of the ingot 11 due to the nitrogen gas formed in the separation layer forming step S20.

In the second embodiment, the separation layers 11d formed in the outer peripheral region 28 through the annular processing step S15 function as a pass for allowing nitrogen gas, which occur inside the radial direction of the ingot 11 in the separation layer forming step S20, to escape out of the ingot 11. Abnormal volume expansion inside in the radial direction of the ingot 11 can be suppressed accordingly. Moreover, the formation of the separation layers 11d in the outer peripheral region 28 can suppress propagation of cracks in an undesired direction (for example, a c-axis direction), and at the same time, can promote outward propagation of the cracks in the c-plane of the ingot 11.

### <Experiments>

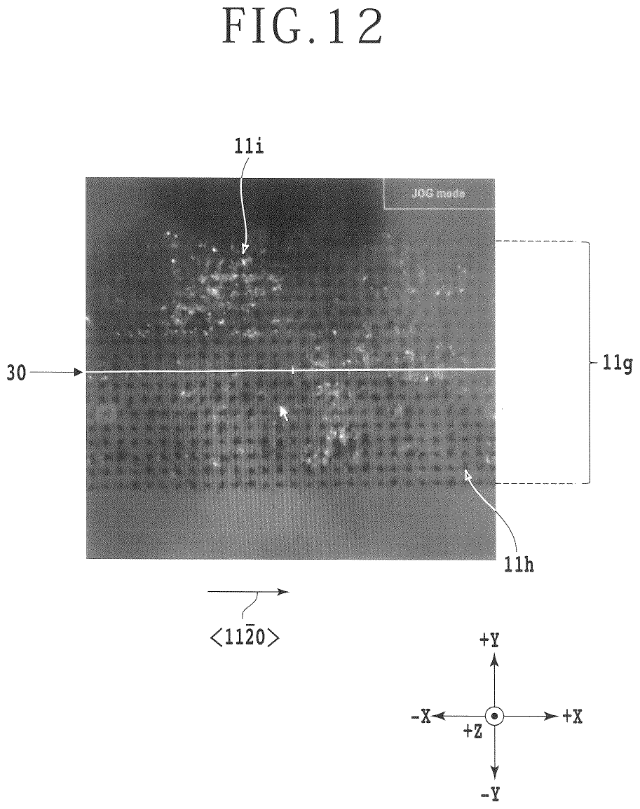

Results of first to third experiments in which the spacing of adjacent focal points and the processing feed rate were changed in the separation layer forming step S20 of the manufacturing method according to the first embodiment will next be described using FIGS. 12 to 15. In the experiments, single-crystal substrates of GaN were processed using the above-mentioned laser processing apparatus 2. The wavelength, repetition frequency, burst number, pass number, spot diameter at each focal point, depth level of focal points, and spacing of focal points were set equal to those in the first embodiment, but the processing feed rate (mm/s) and pulse energy (μJ) were changed as appropriate.

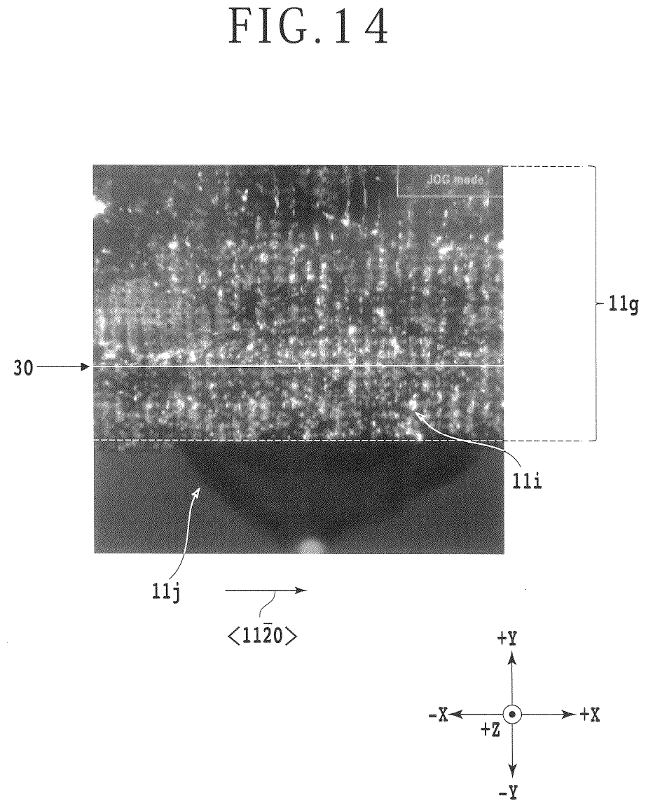

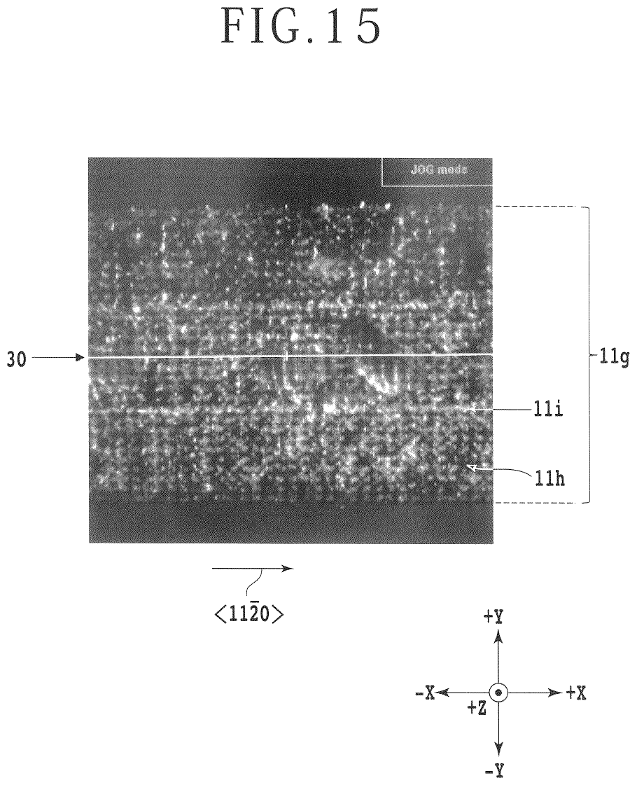

However, the split number of the laser beam L_{C} was set at 6 when processing the single-crystal substrate depicted in FIG. 12, and the split number of the laser beam L_{C} was set at 10 when processing the single-crystal substrates depicted in FIGS. 14 and 15. Further, when processing the single-crystal substrates depicted in FIGS. 12, 14, and 15, respectively, laser processing was applied to three parallel linear regions with the indexing feed rate set at 112.5 μm. However, the laser processing was applied so as to avoid the formation of the overlapping region 22c (see FIG. 7).

FIG. 12 is a photograph of the single-crystal substrate with no sufficient cracks formed between modified regions 11h in the first experiment. The photograph was acquired by imaging the single-crystal substrate on the side of a first surface 11a with a visible light camera after the laser processing. Photographs of FIGS. 14 and 15 to be mentioned later were similarly acquired by imaging with the visible light camera. A straight line that crosses a central area of the image depicted in FIG. 12 in a lateral direction is a reference line 30 as a lateral center line of an imaging field of view. A band-shaped linear region 11g is a region to which the laser processing was applied along the crystal orientations represented by the Muller-Bravais indices (1). In the image, the modified regions 11h are formed at regions depicted by black dots (see FIG. 12), and cracks 11i (see FIG. 12) are formed in bright regions between the modified regions 11h.

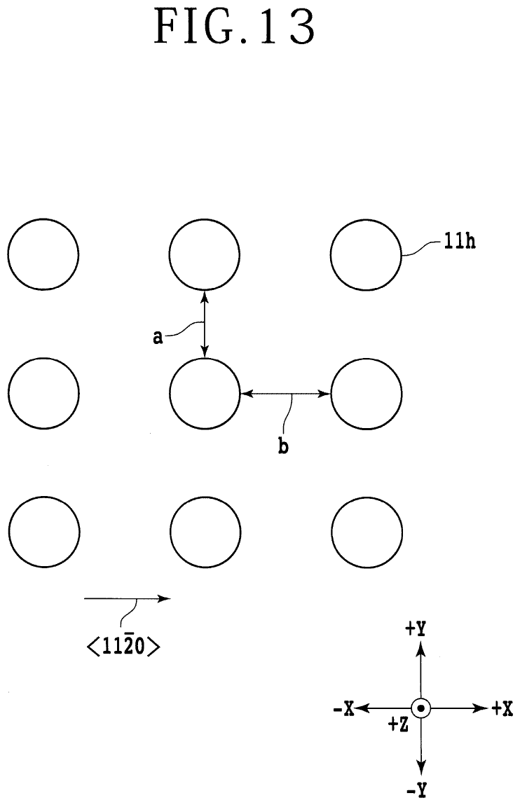

FIG. 13 is a diagram schematically depicting the modified regions 11h in the first experiment. A distance “a” is a spacing between the modified regions 11h themselves aligned side by side along the Y-axis direction (the spacing corresponding to the spacing between the focal points Ps themselves aligned side by side along the Y-axis direction), and its unit is μm. On the other hand, a distance “b” is a spacing between the modified regions 11h themselves aligned side by side along the X-axis direction (the spacing corresponding to the spacing between the focal points Ps themselves aligned side by side along the X-axis direction), and its unit is μm. The distance “b” is determined according to the processing feed rate (in other words, the speed of relative movement of the focal points Ps and the ingot 11) and the repetition frequency.

According to the first through third experiments, it has come to light that laser processing is determined to be good or bad depending on the aspect ratio represented by (b/a). Described specifically, an aspect ratio (b/a) greater than 3.0 leads to an increase in distance between the modified regions 11h themselves, so that cracks 11i do not propagate sufficiently in the XY plane direction as depicted in FIG. 12. On the other hand, an aspect ratio (b/a) smaller than 0.5 leads to a decrease in distance between the modified regions 11h themselves, so that as depicted in FIG. 14, cracks 11i propagate relatively sufficiently in the XY plane direction but relatively large cracks 11j are formed in the Z-axis direction.

FIG. 14 is a photograph of the single-crystal substrate with relatively large cracks 11i formed in the c-axis direction in the second experiment. The cracks 11i propagate in the Z-axis direction (depth direction), and in the photograph depicted in FIG. 14, the cracks 11i are out of focus, and their contours are a little blurred. If the aspect ratio (b/a) is 0.5 or greater and 3.0 or smaller, on the other hand, cracks 11i are allowed to propagate relatively sufficiently in the XY plane direction, and formation of relatively large cracks 11i in the Z-axis direction can be prevented.

FIG. 15 is a photograph of the single-crystal substrate with cracks 11i propagated sufficiently between modified regions 11h and no relatively large cracks 11i formed in the Z-axis direction in the third experiment. The aspect ratio (b/a) may be 0.8 or greater and 2.5 or smaller, and in particular, may be 1.0 or greater and 1.4 or smaller. According to the embodiments, modification, and experiment results mentioned above, the formation of a separation layer 11d in a workpiece with the laser processing apparatus 2 can reduce the slicing margin in the thickness direction of the workpiece compared with the use of a slicer. Moreover, the construction, method, and the like which relate to the above-mentioned embodiments and the like can also be practiced with appropriate modifications within the scope of the object of the present invention.

The present invention is not limited to the details of the above-described preferred embodiments and modification. The scope of the invention is defined by the appended claims and all changes and modifications as fall within the equivalence of the scope of the claims are therefore to be embraced by the invention.

What is claimed is:

1. A manufacturing method of a wafer from a workpiece, the workpiece being an ingot of gallium nitride or a single-crystal substrate of gallium nitride having both a first surface and a second surface located on a side opposite to the first surface, and the wafer having a thickness smaller than a distance between the first surface and the second surface, the method comprising:
a holding step of holding the workpiece at the second surface thereof under suction;
a separation layer forming step of, after the holding step, applying a pulsed laser beam with such a wavelength as to be transmitted through the workpiece to the first surface from a side opposite to the second surface, and with a focal point of the laser beam positioned at a predetermined depth level in the workpiece, relatively moving the workpiece and the focal point along a predetermined direction, thereby forming a separation layer in the workpiece; and
a separation step of, after the separation layer forming step, separating the wafer from the workpiece using the separation layer as a start point, wherein
the predetermined direction in the separation layer forming step forms, in a (0001) plane, an angle of 5° or smaller with respect to crystal orientations represented by the following Miller-Bravais indices (1). [symbol]
112̅0 [symbol] (1)

2. The manufacturing method of a wafer according to claim 1, further comprising:
after the holding step and before the separation layer forming step, an annular processing step of positioning the focal point at the predetermined depth level and applying the laser beam in an annular pattern along an outer peripheral edge of the workpiece, thereby forming an annular separation layer in an outer peripheral region of the workpiece.

3. The manufacturing method of a wafer according to claim 1, wherein,
in the separation layer forming step, after the workpiece and the focal point have been relatively moved in a regular hexagonal pattern so as to follow the predetermined direction, the focal point is moved toward a center in a radial direction of the workpiece, and the workpiece and the focal point are then relatively moved in a smaller regular hexagonal pattern so as to follow the predetermined direction.

4. The manufacturing method of a wafer according to claim 1, wherein,
in the separation layer forming step, the laser beam is split into a plurality of laser beams, focal points of the respective laser beams are arranged so that the focal points are aligned side by side along a first direction, and a second direction orthogonal to the first direction is set to be the predetermined direction.

5. The manufacturing method of a wafer according to claim 4, wherein,
in the separation layer forming step, the focal points are moved along the second direction, are then moved along the first direction, and are thereafter moved along the second direction, and when the focal points are moved along the first direction, the workpiece and the focal points are relatively moved along the first direction so that a first moving region, the first moving region including trajectories of the movement of the focal points along the second direction, and a second moving region, the second moving region including trajectories of the movement of the focal points along the second direction after the movement of the focal points along the first direction, partially overlap each other as seen in the first surface.

6. The manufacturing method of a wafer according to claim 4, wherein,
in the separation layer forming step, the focal points are arranged side by side along the first direction at a spacing of 5 μm or greater and 20 μm or smaller.

7. The manufacturing method of a wafer according to claim 6, wherein,
in the separation layer forming step, separation layers are formed in the first moving region and the second moving region, respectively, and each contain a plurality of modified regions, and,
in each separation layer, the modified regions have an aspect ratio of 0.5 or greater and 3.0 or smaller, the aspect ratio being represented by (b/a) where “a” denotes a spacing (μm) between the modified regions formed side by side along the first direction and “b” denotes a spacing (μm) between the modified regions formed side by side along the second direction by relatively moving the focal points and the workpiece along the second direction.

8. The manufacturing method of a wafer according to claim 1, wherein,
in the separation layer forming step, the laser beam to be applied to the workpiece is applied in a burst mode to the workpiece.
